(19) United States
(12) Patent Application Publication
(10) Pub. No.: US 2008/0289677 A1
(43) Pub. Date: Nov. 27, 2008

(54) COMPOSITE THERMOELECTRIC MATERIALS AND METHOD OF MANUFACTURE

(75) Inventors: Lon E. Bell, Altadena, CA (US); Dmitri Kossakovski, South Pasadena, CA (US)

Correspondence Address: KNOBBE MARTENS OLSON & BEAR LLP, 2040 MAIN STREET, FOURTEENTH FLOOR, IRVINE, CA, 92614, US

(73) Assignee: BSST LLC, Irwindale, CA (US)

(21) Appl. No.: 12/124,559

(22) Filed: May 21, 2008

Related U.S. Application Data
(60) Provisional application No. 60/940,374, filed on May 25, 2007.

(51) Int. Cl. H01L 35/02; H01L 35/34

(52) U.S. Cl. 136/236.1; 136/201; 438/54; 252/62.3 T; 252/500

(57) ABSTRACT

The present disclosure describes a improved composite thermoelectric and an accompanying method. In accordance with one embodiment of the invention, the thermoelectric is constructed in layers from a perform of a stack of layers, and then treated or otherwise modified in order to create a thinner thermoelectric structure.

### CLAIM OF PRIORITY

The present application claims the benefit of priority to U.S. Provisional Patent Application No. 60/940,374, filed May 25, 2007, which is incorporated in its entirety by reference herein.

### BACKGROUND

1. Field of the Invention

The present application relates generally to composite thermoelectric materials and methods of manufacture.

2. Description of the Related Art

Present bulk thermoelectric (TE) materials and the elements made from them are prepared by several methods including (a) melting and recrystallizing into ingots, (b) hot pressing powders into slugs, and (c) extruding materials through dies. Generally, the objective of processing has been to make uniform, identical materials that can then be further processed by slicing, dicing, metalizing, and assembling into arrays. The arrays are typically in the form of TE modules.

Recent advancements in TE materials and their fabrication utilize methods to consolidate TE materials before fabrication into TE elements. Examples of such advancements include heterostructure materials (e.g., as described by Venkatasubramanian, Rama, et al, “Thin-film Thermoelectric Devices With High Room-Temperature Figures of Merit,” Nature, p. 413, 597 (2001) and Harman, Ted, et al., “Quantum Dot Superlattice Thermoelectric Materials and Devices,” Science, p. 297, 2229 (2002)), consolidated powders (e.g., Marlow Industries, Inc., 10451 Vista Park Rd., Dallas, Tex. 75238, USA, “Electrical Resistivity and Seebeck Coefficient of Segmented Thermoelectrics,” 25^{th} Int'l Conf. on Thermoelectrics, Vienna, Austria, 2006), film deposits (e.g., Fraunhofer Institute, Department of Component and Microsystems, Heidenhofstraβe 8, 79110 Freiburg, Germany, “Measuring Methods Applicable to Thermoelectric Materials: Fraunhofer-IPM Capabilities and Services,” 25^{th} Int'l Conf. on Thermoelectrics, Vienna, Austria, 2006), structures formed from nano-scale powders (e.g., by MetaMateria Partners, 1275 Kinnear Rd. Columbus, Ohio 43212), and structures formed from laminates (e.g., Tang, Xinfeng, et al., Wuhan University of Technology, Wuhan 430070, People's Republic of China, “Preparation and Thermoelectric Transport Properties of High-Performance p-type Bi₂Te₃ with Layered Nanostructure,” American Institute of Physics, Applied Physics Letters, p. 90, 012102-1, (2007)). Spark sintering, inert gas sintering, and hydrostatic pressing are among the methods used to consolidate TE materials into bulk materials of sufficient size to form the elements.

It has recently been recognized that cooling performance of devices that operate over a large temperature range can benefit by using segmented or functionally graded TE materials which are composites with varying composition in at least one direction. Such TE materials and processes to fabricate such materials are used to increase efficiency, or improve another performance parameter of the TE elements.

### SUMMARY OF THE INVENTION

The present invention involves, in one embodiment, a thermoelectric structure comprising a plurality of thermoelectric (TE) layers comprising a first TE layer comprising a first material and having a first thickness generally perpendicular to the plurality of TE layers, the first material having a first set of thermoelectric properties. The plurality of TE layers further comprises a second TE layer comprising a second material and having a second thickness generally perpendicular to the plurality of TE layers, the second material having a second set of thermoelectric properties, the second material different from the first material, wherein the plurality of TE layers has a third thickness generally perpendicular to the plurality of TE layers and a width generally parallel to the plurality of TE layers, the third thickness less than the width, wherein the first thickness and the second thickness are selected such that upon operation of the thermoelectric structure, the first TE layer is exposed to a first temperature range, the second TE layer is exposed to a second temperature range, the first set of thermoelectric properties providing more efficient performance than the second set of thermoelectric properties in the first temperature range, the second set of thermoelectric properties providing more efficient performance than the first set of thermoelectric properties in the second temperature range.

In one embodiment, the third thickness is less than 5 millimeters. In one embodiment, the third thickness is less than 1 millimeter. In another embodiment, the third thickness is less than 600 microns. In yet another embodiment, the first thickness is less than 50 microns, and the second thickness is less than 50 microns. In another embodiment, the plurality of TE layers further comprises a third TE layer having a fourth thickness generally perpendicular to the pluarlity of TE layers. In this embodiment, the second TE layer may be between the first TE layer and the third TE layer, the third TE layer comprising the first material. In this embodiment, the third thickness may also be less than 5 millimeters, or in another embodiment, less than 1 millimeter. In yet another embodiment, the third thickness is less than 50 microns.

In one embodiment, the first thickness is less than 50 microns, the second thickness is less than 50 nanometers, and the third thickness is less than 50 microns. In one embodiment, the width is at least 50 millimeters.

Another aspect of the invention involves a method of fabricating a thermoelectric element having a first direction along which a thermal differential is maintained upon operation of the thermoelectric element. The method comprising providing a first thermoelectric (TE) layer of a first TE material, the first TE layer having a first thickness along the first direction and the first TE material having a first set of thermoelectric properties, providing a second TE layer of a second TE material, the second TE layer having a second thickness along the first direction and the second TE material having a second set of thermoelectric properties, structurally coupling the first TE layer and the second TE layer together to form a layered thermoelectric structure, the layered thermoelectric structure having a third thickness along the first direction and a width along a second direction generally perpendicular to the first direction, the third thickness less than the width, and separating a first portion of the layered thermoelectric structure from a remaining portion of the layered thermoelectric structure, the first portion forming at least a part of the thermoelectric element, wherein the first thickness and the second thickness are selected such that upon operation of the thermoelectric element, the first TE layer of the first portion is exposed to a first temperature range, the second TE layer of the first portion is exposed to a second temperature range, the first set of thermoelectric properties providing more efficient performance than the second set of thermoelectric properties in the first temperature range, and the second set of thermoelectric properties providing more efficient performance than the first set of thermoelectric properties in the second temperature range.

In one embodiment of the method, the step of structurally coupling the first TE layer and the second TE layer together comprises electrically coupling the first and second TE layers together. In another embodiment, providing the first TE layer comprises stacking together a plurality of sub-layers of the first TE material. In yet another embodiment, providing the second TE layer comprises stacking together a plurality of sub-layers of the second TE material. In yet another embodiment, providing the second TE layer comprises plating a sub-layer of the second TE material on a sub-layer of the first TE material. In yet another embodiment, providing the second TE layer comprises doping a portion of a sub-layer of the first TE material.

In another embodiment, mechanically coupling the first TE layer and the second TE layer together comprises consolidating the first TE layer and the second TE layer together. In this embodiment, consolidating advantageously comprises spark sintering the first TE layer and the second TE layer together. In a variant of this embodiment, consolidating comprises hot pressing the first TE layer and the second TE layer together.

Yet another embodiment further involves providing a third layer and mechanically coupling the first TE layer and the second TE layer together by mechanically coupling the third layer between the first TE layer and the second TE layer. In this embodiment, the third layer comprises a third TE material. In this embodiment, the third layer advantageously comprises an electrically conductive barrier layer which inhibits migration of atoms from the second TE layer to the first TE layer.

Another aspect of the invention involves a method of fabricating a thermoelectric element using a number of steps. The steps involve providing a preform comprising a plurality of thermoelectric (TE) layers each having a corresponding thickness, the preform having a thickness along a direction generally perpendicular to the plurality of TE layers and a length along a direction generally perpendicular to the thickness, the length greater than the thickness; and reducing the thicknesses of the TE layers, thereby forming a structure having a reduced thickness less than the thickness of the preform. Advantageously, the thicknesses of each of the TE layers prior to being reduced are in a range between 10 microns and 1 millimeter. Advantageously, the thicknesses of each of the TE layers after being reduced are in a range between 1 nanometer and 100 nanometers. In one embodiment, the thicknesses of the TE layers prior to being reduced have ratios to one another, and reducing the thicknesses of the TE layers comprises preserving the ratios of the TE layer thicknesses to one another.

In one embodiment, reducing the thicknesses of the TE layers comprises extrusion of the preform. Advantageously, reducing the thicknesses of the TE layers comprises multiple extrusions of the preform.

In one embodiment, reducing the thicknesses of the TE layers comprises drawing the preform. In another embodiment, reducing the thicknesses of the TE layers comprises stretching the preform along the direction.

In another embodiment, the method further involves stacking a plurality of structures having reduced thicknesses, consolidating the stacked structures to form a stacked, consolidated structure having a thickness, and reducing the thickness of the stacked, consolidated structure. In this embodiment, prefereably, the thickness of the stacked, consolidated structure prior to being reduced is substantially equal to the thickness of the preform prior to being reduced.

### BRIEF DESCRIPTION OF THE DRAWINGS

FIG. 1 depicts the figure of merit as a function of temperature for three different compositions of lead telluride.

FIG. 2A depicts a segmented TE element comprising three materials.

FIG. 2B depicts the operating temperature profile of the TE element in the direction of current flow.

FIG. 3 schematically illustrates an example TE structure in accordance with certain embodiments described herein.

FIG. 4 schematically depicts an example TE element comprising a first TE layer, a second TE layer, and a third TE layer.

FIG. 5 is a flow diagram of an example method of fabricating a TE element in accordance with certain embodiments described herein.

FIG. 6A depicts a plurality of sub-layers stacked together to form the layers of the TE element.

FIG. 6B depicts the consolidated form of the structure of FIG. 6A.

FIG. 7 depicts intervening sub-layers between the TE sub-layers prior to consolidation.

FIG. 8 is a flow diagram of an example method of fabricating a TE element in accordance with certain embodiments described herein.

FIG. 9 schematically illustrates an example fabrication process which scales down layered features by repetitive extrusion.

FIG. 10 schematically illustrates an example fabrication process which re-consolidates multiple layers of thinned material to the original thickness before the extrusion step.

### DETAILED DESCRIPTION

### Segmented Layered Thermoelectric Structures

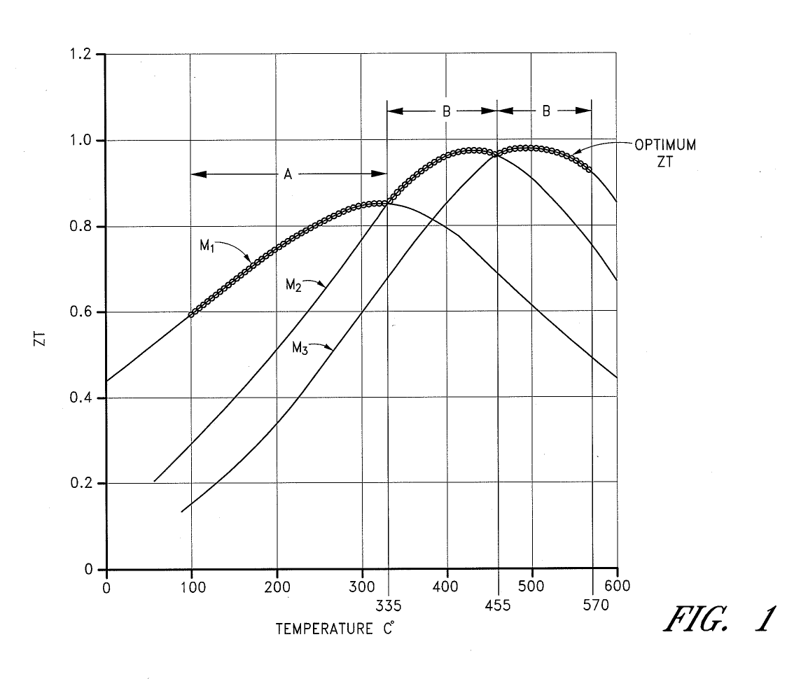

The energy conversion efficiency of a TE element generally increases strongly as the average dimensionless Figure of Merit, ZT, increases. A material can have a set of one or more thermoelectric properties which determine the efficiency of the material's performance at a given temperature, and the figure of merit is an example parameter characteristic of the set of one or more thermoelectric properties. Thus, it is important to find materials or create material combinations that have the highest possible average ZT over the temperature range of use. As an example of TE material properties, FIG. 1 depicts the ZT as a function of temperature for three different compositions of lead telluride (denoted by M₁, M₂, and M₃) doped with various levels of iodine. FIG. 1 shows that no one dopant concentration has the highest ZT over the full range of temperatures from 100° C. to 570° C. Composition M₁ has the highest ZT for temperatures from about 100° C. to about 335° C., composition M₂ has the highest ZT for temperatures from about 335° C. to about 455° C., and composition M₃ has the highest ZT for temperatures from about 455° C. to about 570° C. If TE elements are fabricated from any single composition over the 100° C. to 570° C. temperature range, the average ZT will be substantially lower than that of an element fabricated from all three compositions suitably configured so that each composition is subjected to temperatures in the range in which it has the highest ZT of the three compositions. While FIG. 1 corresponds to various compositions of lead telluride doped with iodine, other TE materials and dopants are also compatible with various embodiments described herein, including but not limited to, compositions of bismuth telluride, compositions of dissimilar TE materials such as lead telluride, skutterudite, bismuth telluride, and TAGS.

Segmented TE elements have been described to improve performance for power generation applications in the past (e.g., Snyder, J. G., “Thermoelectric Power Generation: Efficiency and Compatibility,” Thermoelectrics Handbook, Macro to Nano, Edited by D. M. Rowe, Ph.D., D. Sc. (2006)). Various factors may affect the choice of TE material composition as a function of operating temperature, such as compatibility factor (e.g., as described by Snyder), thermal stability, mechanical stability, and cost, among other factors.

With regard to physical dimensions, the TE segments fabricated in the past have had lengths from 2 millimeters to 15 millimeters along the direction of heat flow or current flow (e.g., T. Caillat et al., “Development of High Efficiency Segmented Thermoelectric Unicouples,” 20^{th} Int'l Conf. on Thermoelectrics (2001), and Y. Shinohara et al., “Thermoelectric Properties of Segmented Pb—Te Systems with Graded Carrier Concentrations,” 16^{th} Int'l Conf. on Thermoelectrics (1997)). Historically, TE elements have had lengths of typically 6 to 20 mm in the direction of heat flow or current flow, so such power generation TE elements can be effectively segmented or functional graded. Even though TE elements used in cooling and heating applications are generally much shorter (about 1 to 2 mm long), segmentation has recently been proposed for such TE elements as well (e.g., Shakouri, Ali, et al., “Cooling Enhancement Using Inhomogeneous Thermoelectric Materials,” 25^{th} Int'l Conf on Thermoelectrics, Vienna, Austria (2006); Müller, E., et al., “Separated Effect of ID Thermoelectric Material Gradients,” 25^{th} Int'l Conf on Thermoelectrics, Vienna, Austria (2006)).

Furthermore, recent innovations allow the effective use of TE elements in the 50-μm to 600-μm length range (see, e.g., L. E. Bell, “Alternate Thermoelectric Thermodynamic Cycles with Improved Power Generation Efficiencies,” 22nd Int'l Conf. on Thermoelectrics, Hérault, France (2003); U.S. Pat. No. 6,812,395, and U.S. Patent Application Publication No. 2004/0261829, each of which is incorporated in its entirety by reference herein). Such TE elements utilize less material to accomplish the same amount of cooling as thicker TE elements. However, such thin TE elements, both for cooling/heating applications and for power generation applications in which the elements have lengths typically between 1 to 5 mm, functional grading is difficult and often impractical. One reason is that manufacturing methods such as crystal growth from melts or powder pressing do not typically provide sufficient control over spatial variation of chemical composition of the material. Such spatial variation is a key for achieving functional grading of thermoelectric properties. Traditional manufacturing methods are typically optimized for creating homogenous materials. If inhomogeneity is desired, the spatial scales of controlled manufacturing can exceed the desired size of this TE elements.

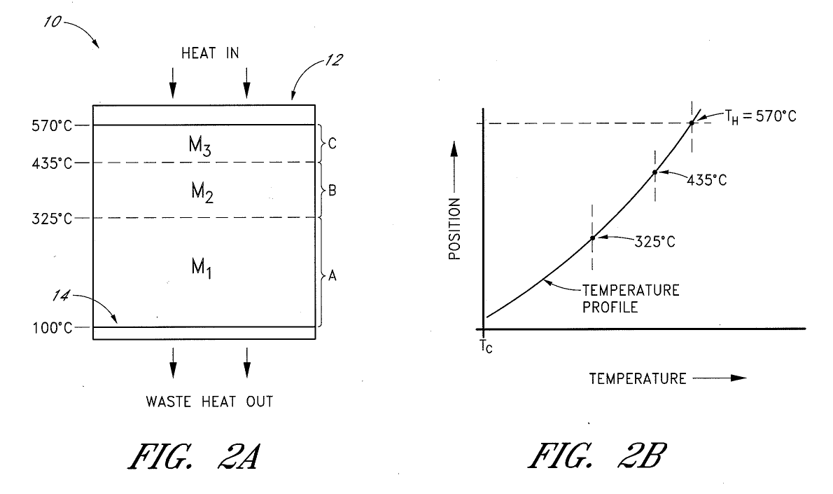

FIG. 2A schematically depicts a segmented TE element 10 comprising layers of the materials M₁, M₂, and M₃ described above and terminated with a hot side electrode 12 on one end of the segmented TE element 10 and a cold side electrode 14 on the other end of the segmented TE element 10. In FIG. 2A, the temperature gradient is vertical with the hot end at the top, and heat flowing vertically downward through the TE element 10. FIG. 2B depicts the operating temperature profile along the TE element 10. By matching the properties of the layered materials of the TE element 10 in the direction of the temperature gradient to the operating temperature profile depicted in FIG. 2B, the average ZT can be tailored to be higher over a broader temperature range.

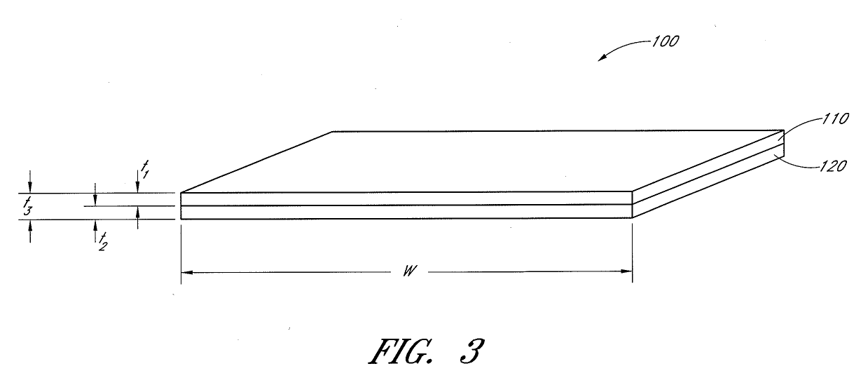

FIG. 3 schematically illustrates an example TE structure 100 in accordance with certain embodiments described herein. The TE structure 100 comprises a plurality of TE layers comprising a first TE layer 110 and a second TE layer 120. The first TE layer 110 comprises a first material and has a first thickness t₁ generally perpendicular to the plurality of TE layers. The first material has a first set of thermoelectric properties. The second TE layer 120 comprises a second material and has a second thickness t₂ generally perpendicular to the plurality of TE layers. The second material has a second set of thermoelectric properties, and the second material is different from the first material. The plurality of TE layers has a third thickness t₃ generally perpendicular to the plurality of TE layers and a width w generally parallel to the plurality of TE layers. The third thickness t₃ is less than the width w. The first thickness t₁ and the second thickness t₂ are selected such that upon operation of the thermoelectric structure 100, the first TE layer 110 is exposed to a first temperature range and the second TE layer 120 is exposed to a second temperature range. The first set of thermoelectric properties provide more efficient performance in the first temperature range than do the second set of thermoelectric properties. The second set of thermoelectric properties provide more efficient performance in the second temperature range than do the first set of thermoelectric properties.

In various embodiments, the third thickness t₃ is less than 5 millimeters, less than 1 millimeter, or less than 600 microns. In certain embodiments, the first thickness t₁ is less than 50 microns. In certain such embodiments, the second thickness t₂ is less than 50 microns. In certain embodiments, the width w is at least 50 millimeters.

Recent approaches to high performance TE material fabrication yield TE materials in several forms, including thin and thick films, ribbons, consolidated powders, and extrusions. By arraying these materials into layers, TE structures in certain embodiments described herein can be formed with are generally planar (e.g., two-dimensional, sheet, ribbon, as schematically illustrated in FIG. 3) with thicknesses in the direction of heat flow or current flow which are much less than the lateral dimensions of the TE structures. In certain embodiments, such generally planar TE structures can advantageously be cut or otherwise separated along one or more lateral directions parallel to the generally planar structure to form individual TE elements each having the same layered structure.

These layered TE elements can have properties that differ with position in the direction of heat flow or current flow (e.g., generally perpendicular to the TE layers 110, 120 of the TE structure 100). In the following description, certain embodiments are described as using generally planar TE materials (e.g., formed as ribbons or sheets). The ribbons or sheets can be formed with a variety of TE material properties that vary with temperature, similar to the variations depicted in FIG. 1. In cooling, heating, and temperature control applications, the total temperature difference between the two sides of the TE element will generally be much less than the total temperature difference for power generation applications depicted in FIG. 1.

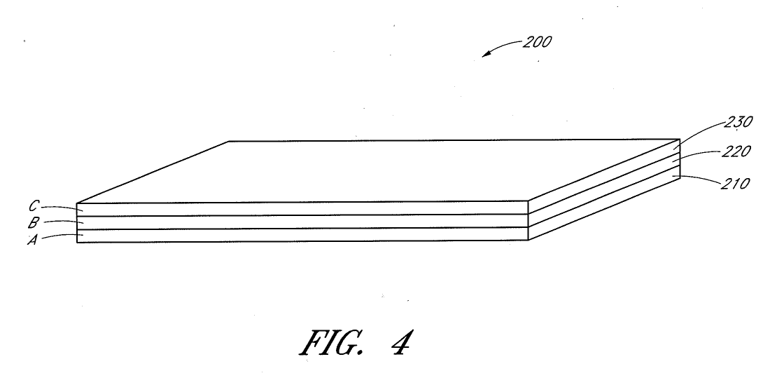

In certain embodiments, the TE materials can be arranged to form layered TE structures that can vary in composition along a direction of thermal gradient or current flow across the TE structure. For example, FIG. 4 schematically depicts an example TE element 200 comprising a first TE layer 210 having a first thickness t₁, a second TE layer 220 having a second thickness t₂, and a third TE layer 230 having a fourth thickness t₄. The first layer 210, the second layer 220, and the third layer 230 comprise three TE materials (denoted by A, B, and C, respectively) that follow the nomenclature of FIG. 1. The layers 210, 220, 230 are arranged so that the layer comprising the TE material with the highest ZT function in the low-temperature range (e.g., layer 210 comprising TE material A) is at the cold side of the TE element 200, and the layer comprising the TE material with the highest ZT function in the high-temperature range (e.g., layer 230 comprising TE material C) is at the hot side of the TE element 200.

In certain embodiments, the first thickness t₁ is less than 50 microns, the second thickness t₂ is less than 50 nanometers, and the fourth thickness t₄ is less than 50 microns. In certain embodiments, the second TE layer 220 is between the first TE layer 210 and the third TE layer 230, and the material of the third TE layer 230 is the same as the material of the first TE layer 210. In various such embodiments, the total thickness of the first, second, and third TE layers 210, 220, 230 is less than 5 millimeters, less than 1 millimeter, or less than 50 microns.

In certain embodiments, the thickness of each layer of the plurality of TE layers is generally in proportion to the temperature ranges across which the TE materials for each layer have the highest ZT. For example, for a TE element 200 having a thickness of Xₜₒₜₐₗ, comprising three layers of equal thermal conductivity, and operated to maintain a total temperature differential ΔTₜₒₜₐₗ between a hot side at temperature T_{H} and a cold side at temperature T_{C} such that ΔTₜₒₜₐₗ=(T_{H}−T_{C}), layer 210 comprising TE material A can have a thickness X_{A}=Xₜₒₜₐₗ*ΔT_{A}/ΔTₜₒₜₐₗ, where ΔT_{A} is the size of the temperature range across which the TE material A of layer 210 has the highest ZT of the three layers. Similarly, layer 220 comprising TE material B can have a thickness X_{B}=Xₜₒₜₐₗ*ΔT_{B}/ΔTₜₒₜₐₗ, where ΔT_{B} is the size of the temperature range across which the TE material B of layer 220 has the highest ZT of the three layers, and layer 230 comprising TE material C can have a thickness X_{C}=Xₜₒₜₐₗ*ΔT_{C}/ΔTₜₒₜₐₗ, where ΔT_{C} is the size of the temperature range across which the TE material C of layer 230 has the highest ZT of the three layers. In certain other embodiments, the thicknesses of the layers can vary from these proportions if, for example, the thermal conductivity of the material A of layer 210 is larger than that of material B of layer 220 and material C of layer 230, in which case the optimum thickness of layer 210 will likely be proportionately greater. In addition to the figure of merit function, other criteria of the TE materials of the layers can be used to apportion material thicknesses. Examples of other such criteria include, but are not limited to, electrical conductivity, cost, fabrication ease, durability, degradation properties with temperature, and any other criteria that result in superior design.

Various methods can be used to fabricate the segmented or functionally graded TE elements described herein. For example, in certain embodiments, it is advantageous that the TE materials of the various layers be suitable for consolidation by hot pressing or spark sintering into the desired final thickness or shape. Spark sintering, or any other suitable consolidation process, converts the layers of TE materials into a graded single large slab, ribbon, or pellet of a thickness suitable for further processing into TE elements. After metalizing the top and bottom surfaces of the layered TE structure and slicing, cutting, or otherwise separating it into TE elements, the top side will be suitable for operation at the hot end and the bottom side for operation at the cold end of a TE power generator or cooling/heating/temperature control system.

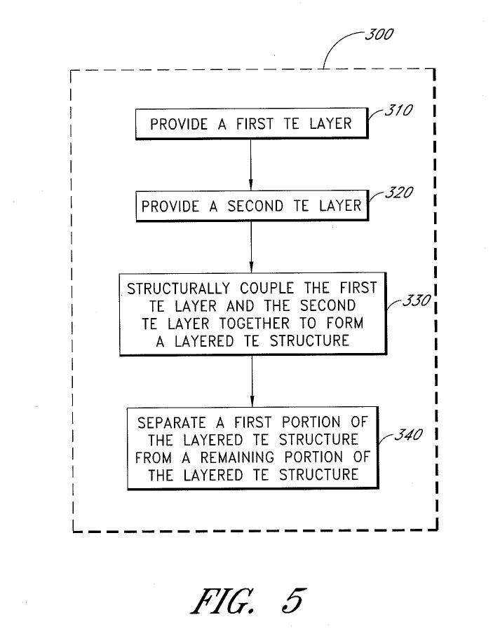

FIG. 5 is a flow diagram of an example method 300 of fabricating a TE element 200 in accordance with certain embodiments described herein. The method 300 comprises providing a first TE layer 210 of a first TE material in an operational block 310. The first TE layer 210 has a first thickness along a first direction and the first TE material has a first set of thermoelectric properties. The method 300 further comprises providing a second TE layer 220 of a second TE material in an operational block 320. The second TE layer 220 has a second thickness along the first direction and the second TE material has a second set of thermoelectric properties. The method 300 further comprises structurally coupling the first TE layer 210 and the second TE layer 220 together to form a layered TE structure in an operational block 330. The layered TE structure has a third thickness along the first direction and a width along a second direction generally perpendicular to the first direction. The third thickness is less than the width. The method 300 further comprises separating a first portion of the layered TE structure from a remaining portion of the layered TE structure in an operational block 340. The first portion forms at least a part of the TE element. The first thickness and the second thickness are selected such that upon operation of the TE element, the first TE layer 210 of the first portion is exposed to a first temperature range and the second TE layer 220 of the first portion is exposed to a second temperature range. The first set of thermoelectric properties provide more efficient performance in the first temperature range than do the second set of thermoelectric properties. The second set of thermoelectric properties provide more efficient performance in the second temperature range than do the first set of thermoelectric properties.

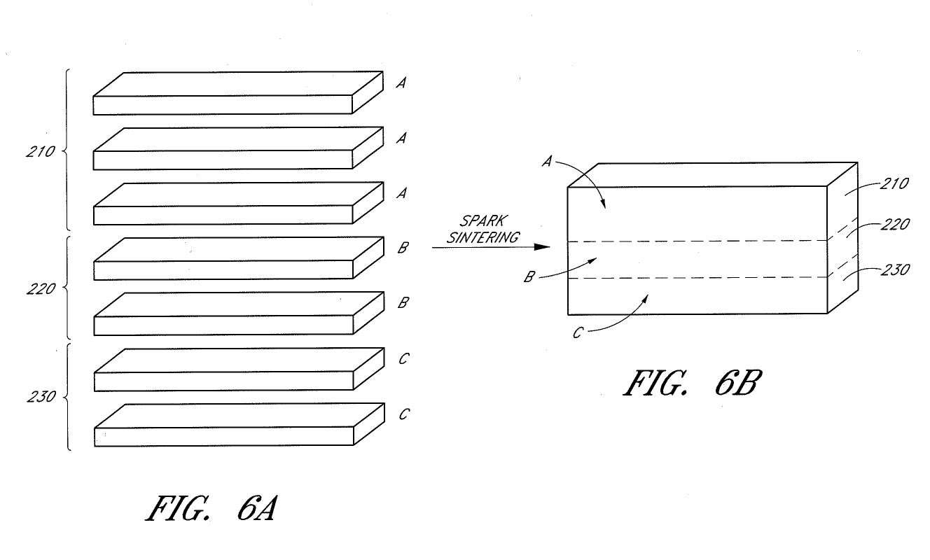

In certain embodiments, providing the first TE layer 210, providing the second TE layer 220, or both can comprise providing thinner sub-layers and stacking the thinner sub-layers together to achieve the desired thicknesses of the first TE layer 210, the second TE layer 220, or both along the direction of thermal gradient. For example, FIG. 6A schematically illustrates an example formation of one or more of the layers of the TE element 200 by stacking multiple thinner sub-layers together. As depicted in FIG. 6A, three sub-layers of a first TE material A (these sub-layers corresponding to the first TE layer 210) are stacked with two sub-layers of a second TE material B (these sub-layers corresponding to the second TE layer 220) and with two sub-layers of a third TE material C (these sub-layers corresponding to a third TE layer 230). The stack can then be sintered to consolidate the sub-layers into the final form as shown in FIG. 6B.

The TE materials that are consolidated may be in any advantageous form or combination of forms. For example, in certain embodiments, prior to the final consolidation, a sub-layer of the TE material A of layer 220 can be plated or attached in any other way onto the bottom-most sub-layer of layer 210, a sub-layer of the TE material B of layer 220 can be plated or attached in any other way onto the top-most sub-layer of layer 230, and the stack can be sintered with the two sub-layers of the TE material B of layer 220 consolidated together. Alternately, the TE material B of layer 220 can formed by a process step in which dopants are added and diffused in a portion of layer 210. This doping process can advantageously change the TE properties of the portion of layer 210 in the mid-temperature range zone to be like the TE material B of layer 220. In addition, the materials may be in powder, ground particles, slurry, or any other form, or combination of forms that can be layered.

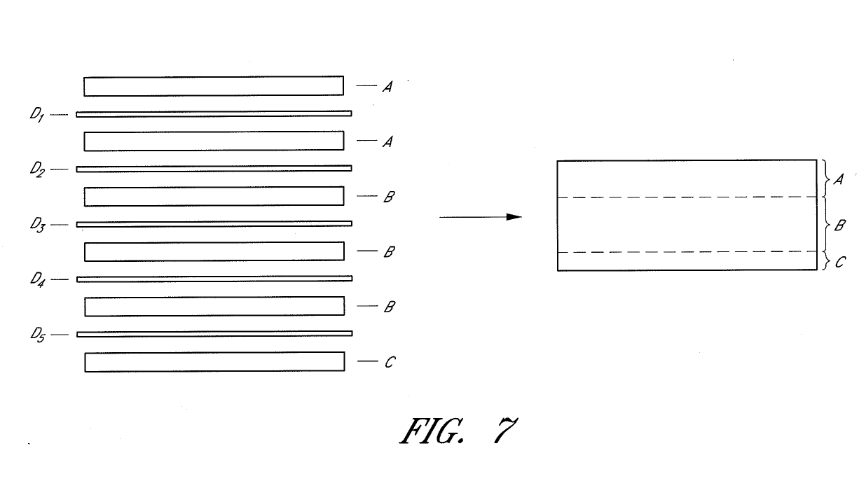

In certain embodiments in which it is not possible or otherwise it is not appropriate to sinter the unaltered TE materials together, the layers, sheets, or ribbons of the various TE materials can be interleaved with materials that produce suitable bonds. For example, the surface of layer 210 that mates with layer 220 could be highly lead-rich (and suitably doped) while the mating surface of layer 220 could be highly telluride-rich (and suitably doped). Exposure to moderate temperatures and pressures could then cause layer 210 and layer 220 at the interface to produce lead telluride, which may have undesirable TE properties. Therefore, in certain embodiments, an interface material can be interposed between layer 210 and layer 220 to produce an interface region having acceptable TE properties and which bonds the two layers together. For example, as schematically depicted in FIG. 7, interface material D₂ can be interposed between layer 210 and layer 220, and interface material D₅ can be interposed between layer 220 and layer 230. For example, as also schematically illustrated by FIG. 7, one or more interface materials can be interposed between sub-layers which form a TE layer (e.g., interface material D₁ between the sub-layers of the first TE layer 210, and/or interface materials D₃ and D₄ between sub-layers of the second TE layer 220). Examples of possible interface materials include, but are not limited to, metals such as indium, nickel, molybdenum, tungsten, platinum, palladium, gold, and silver, metallic allows such as TiSiN, TaSiN, and SnTe, and highly engineered materials such as layers of carbon nanotubes or other approaches. Interface connections between compatible TE materials (e.g., BiTE based materials) can be fabricated by bonding of reactive components (e.g., suitably-doped Bi-rich surface in contact with suitably-doped Te-rich surface bonds reactively to form a Bi—Te interface) Also, the interface may be treated with a material such as gold or nickel to promote low temperature diffusion bonding.

The interleaving layers or sheets of certain embodiments can impart other properties important to achieving the desired final properties of the laminate structure as well. Further improvements may occur if the bond zone were as thin as possible. Alternately, the interface could be a separate layer or sheet of compatible TE material with a lower melting or diffusion bond temperature. The bonding materials or surface preparation could be applied by vapor deposition, ion implantation, molecular beam epitaxy, sputtering, plating, spraying, painting, or any other suitable process. The bonding materials could be in powder, liquid, film, amalgam, diffusion bonding agent, separate sheet, or any other material form.

Manufacturing efficiency, cost, performance, or other benefits may be further realized by attaching electrode surfaces to the cold and/or hot side outer faces of the TE element during the bonding process. Thus, the process also could attach electrical connectors (metalized electrodes) both for connection with the source of electric power and connection to hot-side and cold-side heat sinks. The electrode material may be a composite that contains transition materials that act as diffusion barriers for otherwise incompatible materials. For example, in the TE element 10 of FIG. 2A, iron electrodes could be nickel plated to effect bonding. Alternately, a layer of nickel telluride, or any other suitable transition or barrier materials, could be positioned between the electrodes and the adjoining TE material. The hot-side and cold-side electrode materials could be of different composition to be compatible with braze, solder, or other external attachment methods. Also, the electrode materials may be selected to reduce mechanically or thermally induced stresses or to otherwise improve device performance, cost, durability, or for any other advantageous reason.

For certain material systems, TE materials that would benefit by being adjacent to one another may not be compatible to allow direct connection (e.g., by sintering). For example, bismuth telluride is “poisoned” by the presence of lead at high temperatures (i.e., its TE figure of merit ZT is degraded substantially by the lead), such that it could be adversely affected if mated directly to lead telluride (e.g., in power generator TE elements). In certain embodiments, interlayers or barrier layers may be advantageously positioned between the layers to inhibit migration of atoms from the second TE layer to the first TE layer, thereby allowing otherwise incompatible materials to be used to form the TE element. The barrier layers can be coatings, thin metallic or electrically conductive ceramic layers, or any other suitable material systems. Advantageously, in certain embodiments, the barrier layers will be thin and have good bonding qualities and compatible electrical conductivity properties to maintain or enhance the advantages of segmentation or functional grading. For example, the barrier layer can comprise a third, mutually-compatible TE material and have bonding agents on its surfaces. Thus between two adjacent TE material layers, the joint can comprise multiple materials, constructed in a sequence that as a whole achieves the desired properties of bonding while providing compatibility, diffusion, barriers, lowest practical degradation of element performance, or any other interfacial properties required. One example of such a barrier joint can be a bond created by transient liquid phase bonding techniques as described in U.S. Patent Publication No. US 2006/0151871, application Ser. No. 11/031,435 entitled High Temperature, Stable SIC Device Interconnects and Packages Having Low Thermal Resistance to Mehrotra.

### Scale-Down Process for Thermoelectric Fabrication

A variety of recent studies demonstrate that improved performance of the thermoelectric materials can be achieved by forming nanometer-scale heterogeneous structures in specific material systems. The enhanced thermoelectric performance of these nanostructured materials are thought to result from quantum confinement of electronic properties and from disruptions of pathways for phonon propagation in the medium. Such nanometer-scale structures can be in a form of small particles aggregated in a macroscopic object (see, e.g., U.S. Patent Application Publication No. 2006/0249704, which is incorporated in its entirety by reference herein) or particle-like inclusions in a host matrix (see, e.g., U.S. Patent Application Publication No. 2006/0102224, which is incorporated in its entirety by reference herein). Another typical shape is a sequence of alternating material layers, each layer having characteristic size of several nanometers (see, e.g., U.S. Pat. No. 6,452,206, which is incorporated in its entirety by reference herein).

The layered materials are typically grown in a Molecular Beam Epitaxy (MBE) apparatus which allows precise control of layer composition and geometry. This process is an example of a “bottom-up” fabrication approach, where features of the desired shape and composition are fabricated at the designed scale, and then the material is built up to macroscopic scale while preserving the improved properties. However, a known drawback of the MBE fabrication method is its low speed and high cost. In addition, MBE-fabricated structures can suffer from parasitic losses due to unintended variations in the various properties (e.g., electrical and thermal conductivity) in the material.

Certain embodiments described herein advantageously utilize a “top-down” fabrication approach. For example, a material preform is first designed at macroscopic scale with the desired ratios of feature sizes (e.g., ratios of layer thicknesses to one another). A scale-down processing step is then performed on the preform so that the scale is reduced while the ratios of the feature sizes are preserved. The resultant material is then repeatedly subjected to scale-down steps, until the absolute sizes of the features of interest are reduced to the desired dimensions while maintaining the ratios of feature sizes.

In certain embodiments, a top-down fabrication method as described herein advantageously provides more flexibility in the processing since prior to processing, the material structure is defined on the macroscopic scale, where the design freedom and material handling is greatly simplified compared to nano-scale structures. In certain embodiments, a top-down fabrication method as described herein advantageously provides larger production volumes since the material can be produced in large volumes from macroscopic preforms. In addition, certain embodiments of the top-down fabrication method described herein produce TE elements which do not suffer as much from parasitic losses as do MBE-fabricated structures.

The top-down fabrication method described herein is analogous to top-down manufacturing processes used for drawing an optical fiber. A typical optical fiber comprises a core and a cladding surrounding the core. Various physical parameters (e.g., core diameter, refractive indices of the core and the cladding) define the optical characteristics of the fiber. A typical core diameter is 9 micron, and this dimension needs to be precisely controlled. A typical diameter of the cladding is 125 micron. A common optical fiber fabrication approach includes drawing the fiber from a much larger preform. Preform diameters can be around 25 mm, with the core diameter of about 1.8 mm. The fiber is drawn in a single processing step, thereby achieving scaling down of the features by a factor of 200.

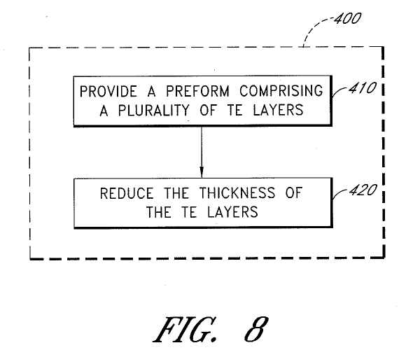

FIG. 8 is a flow diagram of an example method 400 of fabricating a TE element in accordance with certain embodiments described herein. The method 400 comprises providing a preform in an operational block 410. The preform comprises a plurality of TE layers each having a corresponding thickness. The preform has a thickness along a direction generally perpendicular to the plurality of TE layers and a length along a direction generally perpendicular to the thickness. The length is greater than the thickness. The method 400 further comprises reducing the thicknesses of the TE layers in an operational block 420. A structure is formed in which the structure has a reduced thickness less than the thickness of the preform.

In certain embodiments, the thicknesses of each of the TE layers prior to being reduced are in a range between 10 microns and 1 millimeter. In certain embodiments, the thicknesses of each of the TE layers after being reduced are in a range between 1 nanometer and 100 nanometers. In certain embodiments, the thicknesses of the TE layers prior to being reduced have ratios to one another, and reducing the thicknesses of the TE layers comprises preserving the ratios of the TE layer thicknesses to one another.

In certain embodiments, fabrication of multilayer TE materials comprises extrusion of a preform. Extrusion is an example of severe plastic deformation and is a known process in the field of thermoelectric materials (e.g., U.S. Pat. No. 6,617,504 issued to Kajihara et al., which discloses an extrusion apparatus for making thermoelectric elements that reduces the size of the preform by a factor of approximately 6, and which is incorporated in its entirety by reference herein). Millimeter-scale parts are commonly made by extruding thermoelectric materials. Both homogeneous and heterogeneous materials have been successfully extruded in the past. Extrusion can be applied in certain embodiments described herein for top-down manufacturing of nanostructured thermoelectric materials. Extrusion has been shown to form nanoscale structures in other materials, such as aluminum (e.g., “Hydrostatic extrusion and nanostructure formation in an aluminum alloy,” M. Lewandowska, poster at E-MRS Fall Meeting 2003, Symposium G). The technique of “equal channel angular extrusion” has previously been applied to thermoelectric materials (e.g., U.S. Pat. No. 6,883,359 issued to Hartwig, Jr. on Apr. 26, 2005, which is incorporated in its entirety by reference herein).

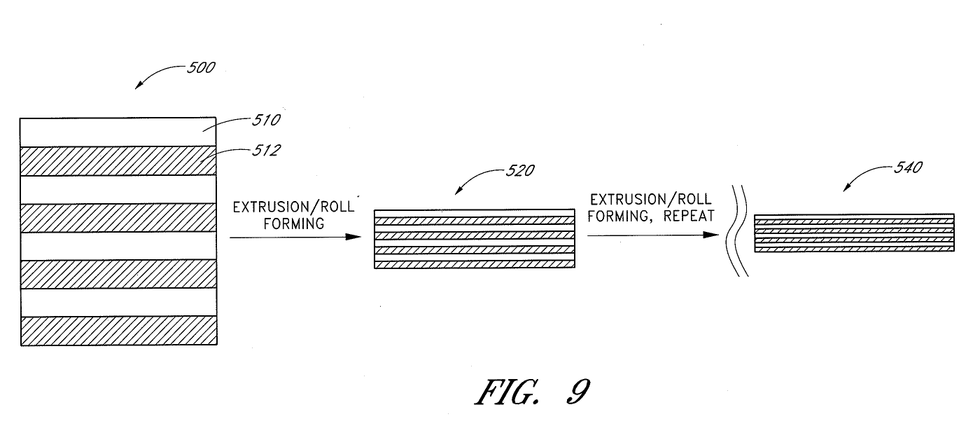

An example fabrication process utilizing extrusion to fabricate a flat multilayer TE structure of alternating materials with a periodicity of few nanometers or tens of nanometers is schematically illustrated by FIG. 9. A scaled-up preform 500 comprises a desired number of layers and material alterations for the resultant structure, but the thicknesses of the layers in the preform are macroscopic (e.g., 100 micron each). The layers are combined and, if desirable, bonded together to form a monolithic laminate structure. A variety of consolidation and bonding approaches can be used to build such a structure as disclosed herein in the “Segmented Layered Thermoelectric Structures” section. Alternately, individual layers can be combined and consolidated in the initial step of extrusion or any other form of scale reduction. The preform 500 can serve as a macroscopic laminated pre-cursor for a nanostructured material as described more fully below.

The laminate structure of the preform 500 is then extruded at elevated temperatures and pressures where the materials of the laminate structure become plastically deformable. In certain embodiments, the extrusion is performed by pressing the laminate structure in an extrusion mask. For the purposes of scaling-down, the extrusion mask of certain embodiments does not have any special features. For example, the extrusion mask can comprise a slit with the height smaller than the total thickness of the laminate structure. The ratio of the slit height to the laminate structure thickness defines the scale reduction factor of the single extrusion step.

The total thickness of the laminate structure is reduced during the extrusion, and the thickness of individual layers is scaled down proportionately such that the ratios of layer thicknesses stays the same. For example, as shown schematically in FIG. 9, for the preform 500 comprising alternating layers 510, 512 the multilayer structure 520 resulting from the extrusion/roll forming process has individual layers 530, 532 with reduced thicknesses in which the alternating structure of the preform 500 is preserved after the scaling step. This extrusion process can be repeated, possibly multiple times, with each extrusion reducing the thickness of the laminate structure further. After a selected number of processing steps, a structure 540 with layer thicknesses between 1 nanometer and 100 nanometer can be achieved as schematically illustrated in FIG. 9, thereby enabling quantum confinement. While MBE fabrication methods can produce very defined features, including dot-like structures, extrusion fabrication methods typically produce layer-like structures. In certain embodiments, the extrusion fabrication methods described herein advantageously provide nanoscale-sized structures which enable quantum confinement and mechanically robust materials.

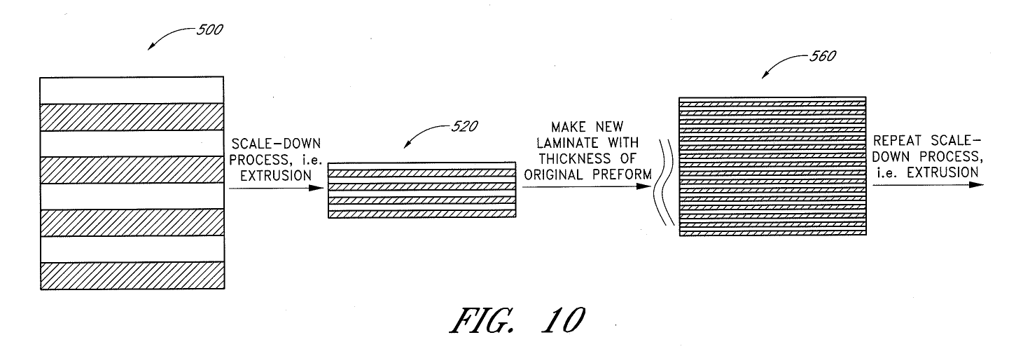

In certain embodiments, after the scale-down process of the preform 500, the resulting laminate structure 520 can be stacked with other laminate structures 520. Using consolidation/bonding processes as described above, the stacked laminate structures 520 can be formed into a new laminated preform 560. This new laminated preform 560 will have an increased number of layers within the thickness of the preform 500. An example of such a process is schematically illustrated by FIG. 10.

In certain embodiments, a sufficient number of thinned layers are stacked together to form a new preform 560 having substantially the same thickness as the original laminate structure thickness of the preform 500. In certain such embodiments, this thickness can be achieved if the number of combined thinned laminate structures equals the scaling factor of a single extrusion step. For example, if a single extrusion step has a scale-down factor of 10, then 10 thinned laminate structures can be stacked together and consolidated to reach the original laminate structure thickness. The advantage of constant thickness of material prior to each extrusion step is that only one extrusion mask is required even if the extrusion process is repeated multiple times. While extrusion is a severe plastic deformation process, in certain embodiments, it is advantageous to use multiple, repetitive extrusion steps to produce nanoscale structures, rather than a single extrusion step.

In certain embodiments, production of the nano-structured thermoelectric material will utilize a total scaling factor of about 10,000 (assuming starting with layers having thicknesses of about 100 microns and the desired layer thickness of about 10 nanometers). If a single processing step provides a scale-down factor of 10, then 4 consecutive processing rounds can be used to achieve the desired geometry. A similar repetitive rolling and folding process was demonstrated in application to metals (e.g., Hebert, R. J. and Perepezko, J. H., “Structural Transformations in Crystalline and Amorphous Multilayer Samples During Cold Rolling,” Scripta Materialia, Vol. 49, pages 933-939 (2003)). Starting with an initial material thickness of 1 micron of laminated material, nanometer-scale layers were developed after about 100 rolling and folding steps. Scaling factor of each rolling step can be about 2, so the thickness after rolling step is half that of the original.

In certain embodiments, alternative scale-down processes can be used to fabricate the desired nanostructure layering of TE materials. Other approaches to form nanometer-scale thermoelectric structures with scale down processes compatible with certain embodiments described herein include, but are not limited to, extrusion into a flat slab, extrusion into a round billet, equal channel angular extrusion, and other shape deformation methods that result in scaling down of the characteristic features of the material.

In certain embodiments, the temperature, pressure, timing, and other parameters of the scaling-down forming process are advantageously adjusted to optimize the process. Too low of a temperature will not make the material plastic enough to enable efficient extrusion. The extrusion temperatures of certain embodiments are close to the melting temperature of the worked material, e.g., in the range of 60% to 80% of the melting temperature on the absolute (Kelvin) scale. Therefore, if two or more materials are being co-extruded, the temperature of the extrusion process is selected in certain embodiments to be at a value that lies in the range of plastic deformation of each material. For example, as described in U.S. Pat. No. 3,220,199 a variety of thermoelectric materials can be extruded at temperatures generally above 400° C. These materials include, for example, Pb—Te, Ge—Te, Zn—Sb, Bi—Te, Ge—Bi—Te, Bi—Te—Se, Ag—Sb—Te, Ag—Sb—Ge—Te, In—As—P and other suitable materials in various compositions.

Too high of a temperature and/or too long of a dwelling time in the extrusion zone will lead to increased diffusion between layers. Such processing parameters can result in the degradation of a well-defined heterogeneous structure, thereby eliminating enhancement of the TE properties. The unwanted diffusion can be prevented in certain embodiments by optimizing the parameters of the extrusion process and/or by adding a diffusion-inhibiting barrier layer (e.g., nickel) between the layers of extruded material. In certain embodiments, the diffusion-inhibiting barrier layer can be added as one of the original steps of preform preparation, prior to the first extrusion process.

Various embodiments of the present invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

What is claimed:

1. A thermoelectric structure comprising:
a plurality of thermoelectric (TE) layers comprising:
a first TE layer comprising a first material and having a first thickness generally perpendicular to the plurality of TE layers, the first material having a first set of thermoelectric properties; and
a second TE layer comprising a second material and having a second thickness generally perpendicular to the plurality of TE layers, the second material having a second set of thermoelectric properties, the second material different from the first material, wherein the plurality of TE layers has a third thickness generally perpendicular to the plurality of TE layers and a width generally parallel to the plurality of TE layers, the third thickness less than the width, wherein the first thickness and the second thickness are selected such that upon operation of the thermoelectric structure, the first TE layer is exposed to a first temperature range, the second TE layer is exposed to a second temperature range, the first set of thermoelectric properties providing more efficient performance than the second set of thermoelectric properties in the first temperature range, the second set of thermoelectric properties providing more efficient performance than the first set of thermoelectric properties in the second temperature range.

2. The thermoelectric structure of claim 1, wherein the third thickness is less than 5 millimeters.

3. The thermoelectric structure of claim 1, wherein the third thickness is less than 1 millimeter.

4. The thermoelectric structure of claim 1, wherein the third thickness is less than 600 microns.

5. The thermoelectric structure of claim 1, wherein the first thickness is less than 50 microns.

6. The thermoelectric structure of claim 5, wherein the second thickness is less than 50 microns.

7. The thermoelectric structure of claim 1, wherein the plurality of TE layers further comprises a third TE layer having a fourth thickness generally perpendicular to the plurality of TE layers.

8. The thermoelectric structure of claim 7, wherein the second TE layer is between the first TE layer and the third TE layer, the third TE layer comprising the first material.

9. The thermoelectric structure of claim 8, wherein the third thickness is less than 5 millimeters.

10. The thermoelectric structure of claim 8, wherein the third thickness is less than 1 millimeter.

11. The thermoelectric structure of claim 8, wherein the third thickness is less than 50 microns.

12. The thermoelectric structure of claim 7, wherein the first thickness is less than 50 microns, the second thickness is less than 50 nanometers, and the third thickness is less than 50 microns.

13. The thermoelectric structure of claim 1, wherein the width is at least 50 millimeters.

14. A method of fabricating a thermoelectric element having a first direction along which a thermal differential is maintained upon operation of the thermoelectric element, the method comprising:
providing a first thermoelectric (TE) layer of a first TE material, the first TE layer having a first thickness along the first direction and the first TE material having a first set of thermoelectric properties;
providing a second TE layer of a second TE material, the second TE layer having a second thickness along the first direction and the second TE material having a second set of thermoelectric properties;
structurally coupling the first TE layer and the second TE layer together to form a layered thermoelectric structure, the layered thermoelectric structure having a third thickness along the first direction and a width along a second direction generally perpendicular to the first direction, the third thickness less than the width; and
separating a first portion of the layered thermoelectric structure from a remaining portion of the layered thermoelectric structure, the first portion forming at least a part of the thermoelectric element, wherein the first thickness and the second thickness are selected such that upon operation of the thermoelectric element, the first TE layer of the first portion is exposed to a first temperature range, the second TE layer of the first portion is exposed to a second temperature range, the first set of thermoelectric properties providing more efficient performance than the second set of thermoelectric properties in the first temperature range, and the second set of thermoelectric properties providing more efficient performance than the first set of thermoelectric properties in the second temperature range.

15. The method of claim 14, wherein structurally coupling the first TE layer and the second TE layer together comprises electrically coupling the first and second TE layers together.

16. The method of claim 14, wherein providing the first TE layer comprises stacking together a plurality of sub-layers of the first TE material.

17. The method of claim 14, wherein providing the second TE layer comprises stacking together a plurality of sub-layers of the second TE material.

18. The method of claim 14, wherein providing the second TE layer comprises plating a sub-layer of the second TE material on a sub-layer of the first TE material.

19. The method of claim 14, wherein providing the second TE layer comprises doping a portion of a sub-layer of the first TE material.

20. The method of claim 14, wherein mechanically coupling the first TE layer and the second TE layer together comprises consolidating the first TE layer and the second TE layer together.

21. The method of claim 20, wherein consolidating comprises spark sintering the first TE layer and the second TE layer together.

22. The method of claim 20, wherein consolidating comprises hot pressing the first TE layer and the second TE layer together.

23. The method of claim 14, further comprising providing a third layer and mechanically coupling the first TE layer and the second TE layer together comprises mechanically coupling the third layer between the first TE layer and the second TE layer.

24. The method of claim 23, wherein the third layer comprises a third TE material.

25. The method of claim 23, wherein the third layer comprises an electrically conductive barrier layer which inhibits migration of atoms from the second TE layer to the first TE layer.

26. A method of fabricating a thermoelectric element, the method comprising:
providing a preform comprising a plurality of thermoelectric (TE) layers each having a corresponding thickness, the preform having a thickness along a direction generally perpendicular to the plurality of TE layers and a length along a direction generally perpendicular to the thickness, the length greater than the thickness; and
reducing the thicknesses of the TE layers, thereby forming a structure having a reduced thickness less than the thickness of the preform.

27. The method of claim 26, wherein the thicknesses of each of the TE layers prior to being reduced are in a range between 10 microns and 1 millimeter.

28. The method of claim 26, wherein the thicknesses of each of the TE layers after being reduced are in a range between 1 nanometer and 100 nanometers.

29. The method of claim 26, wherein the thicknesses of the TE layers prior to being reduced have ratios to one another, and reducing the thicknesses of the TE layers comprises preserving the ratios of the TE layer thicknesses to one another.

30. The method of claim 26, wherein reducing the thicknesses of the TE layers comprises extrusion of the preform.

31. The method of claim 30, wherein reducing the thicknesses of the TE layers comprises multiple extrusions of the preform.

32. The method of claim 26, wherein reducing the thicknesses of the TE layers comprises drawing the preform.

33. The method of claim 26, wherein reducing the thicknesses of the TE layers comprises stretching the preform along the direction.

34. The method of claim 26, further comprising:
stacking a plurality of structures having reduced thicknesses;
consolidating the stacked structures to form a stacked, consolidated structure having a thickness; and
reducing the thickness of the stacked, consolidated structure.

35. The method of claim 34, wherein the thickness of the stacked, consolidated structure prior to being reduced is substantially equal to the thickness of the preform prior to being reduced.
